(19) United States
(12) Patent Application Publication
(10) Pub. No.: US 2020/0106248 A1
(43) Pub. Date: Apr. 2, 2020

(54) ELECTROMAGNETIC SHIELD COMPONENT, WIRE HARNESS, AND METHOD FOR MANUFACTURING ELECTROMAGNETIC SHIELD COMPONENT

(71) Applicants: AUTONETWORKS TECHNOLOGIES, LTD., Yokkaichi-shi , Mie (JP); SUMITOMO WIRING SYSTEMS, LTD., Yokkaichi-shi , Mie (JP); SUMITOMO ELECTRIC INDUSTRIES, LTD., Osaka-shi, Osaka (JP)

(72) Inventors: Takeshi SHIMIZU, Yokkaichi (JP); Hirotaka BABA, Yokkaichi (JP)

(73) Assignees: AUTONETWORKS TECHNOLOGIES, LTD., Yokkaichi-shi, Mie (JP); SUMITOMO WIRING SYSTEMS, LTD., Yokkaichi-shi, Mie (JP); SUMITOMO ELECTRIC INDUSTRIES, LTD., Osaka-shi, Osaka (JP)

(21) Appl. No.: 16/616,519

(22) PCT Filed: May 29, 2018
(86) PCT No.: PCT/JP2018/020435

§ 371 Date: Nov. 25, 2019

(30) Foreign Application Priority Data
Jun. 15, 2017 (JP) 2017-117713

(51) Int. Cl. H02G 3/04

(52) U.S. Cl. CPC H02G 3/0481; H05K 9/0088; H02G 3/0406

(57) ABSTRACT

An electromagnetic shield component that includes a first tube that has conductivity; a flexible shield; and a second tube that is put onto the first tube in a state in which the flexible shield is disposed between the first tube and the second tube, wherein the second tube, in an inner circumferential surface thereof, has a first protrusion that protrudes toward the first tube and is in contact with the first tube in a pressed state, and a second protrusion that protrudes toward the flexible shield and holds the flexible shield between the first tube and the second tube, and the first and second protrusions are provided over an entire length of the inner circumferential surface in a circumferential direction.

### BACKGROUND

The present disclosure relates to an electromagnetic shield component, a wire harness, and a method for manufacturing the electromagnetic shield component.

As a conventional wire harness installed in a vehicle, a wire harness is known in which the circumferential surface of a wire is covered with an electromagnetic shield component as a countermeasure against electromagnetic noise (see JP 2007-280814A, for example).

In the electromagnetic shield component, an end portion of a tubular member that has conductivity and an end portion of a braided member that has conductivity are connected to each other by a connecting member, and a wire inserted in a continuous tubular body formed of the tubular member and the braided member is electromagnetically shielded.

In an electromagnetic shield component as described above, the tubular member and the braided member are connected to each other by a crimp ring made of a metal. The crimp ring squeezes, from the outside, the braided member that is put onto (externally fitted to) the end portion of the tubular member, and the braided member is held between an outer circumferential surface of the tubular member and an inner circumferential surface of the crimp ring. Such a crimp ring has a circular arc-shaped portion and a bent and protruding portion that protrudes from the circular arc-shaped portion toward the outer circumferential side thereof in the radial direction, and the braided member is kept in a state of being squeezed to the tubular member by the plastic processing of the bent and protruding portion.

### SUMMARY

In the electromagnetic shield component as described above, the tubular member and the braided member are connected to each other by the metal crimp ring. The bent and protruding portion of the crimp ring protrudes in the radial direction in the location in which the braided member and the tubular member are connected to each other, and thus there is concern that this protrusion will cause a localized increase in the size of the electromagnetic shield component.

An exemplary aspect of the disclosure provides an electromagnetic shield component with which it is possible to suppress a localized increase in the size thereof, and a wire harness that includes said electromagnetic shield component.

An electromagnetic shield component according to an exemplary aspect includes a first tube that has conductivity; a flexible shield; and a second tube that is put onto the first tube in a state in which the flexible shield is disposed between the first tube and the second tube, wherein the second tube, in an inner circumferential surface thereof, has a first protrusion that protrudes toward the first tube and is in contact with the first tube in a pressed state, and a second protrusion that protrudes toward the flexible shield and holds the flexible shield between the first tube and the second tube, and the first and second protrusions are provided over an entire length of the inner circumferential surface in a circumferential direction.

With this configuration, since the second protrusion is provided, which protrudes toward the flexible shield from the inner circumferential surface of the second tube that is put on the first tube and holds the flexible shield between the first tube and the second tube, the flexible shield can be held between the first tube and the second tube by the second protrusion. Consequently, a conventional bent and protruding portion can be made unnecessary, and thus, a localized increase in the size of the electromagnetic shield component can be suppressed. Moreover, since the second protrusion is provided over the entire length of the inner circumferential surface of the second tube in the circumferential direction, the protrusion can apply uniform pressure to the flexible shield. Furthermore, the presence of the first protrusion that is in contact with the first tube in a pressed state makes it possible to fix the first tube and the second tube to each other.

It is preferable that in the electromagnetic shield component, an outer diameter of the second tube in portions where the first and second protrusions are formed is smaller than the outer diameter of the second tube in portions where the first and second protrusions are not formed.

With this configuration, the outer diameter of the second tube in the portions where the first and second protrusions are formed is smaller than the outer diameter of the second tube in the portions where the first and second protrusions are formed. In other words, a first and second protrusions can be obtained by reducing the diameter of the second tube through plastic processing.

It is preferable that in the electromagnetic shield component, the protruding amount of the first protrusion from the inner circumferential surface is larger that than the protruding amount of the second protrusion from the inner circumferential surface.

With this configuration, the protruding amount of the first protrusion is larger than the protruding amount of the second protrusion, and therefore it is possible to suppress excessive pressing force from the second protrusion from being applied to the flexible shield, while reliably fixing the first tube and the second tube to each other with use of the first protrusion.

A wire harness accroding to an exemplary aspect includes the electromagnetic shield component according to any one of the above-described configurations and a wire inserted in the electromagnetic shield component.

With this configuration, it is possible to provide a wire harness that achieves a similar effect to any one of the above-described effects.

A method of manufacturing an electromagnetic shield component according to an exemplary aspect includes: forming a first protrusion over an entire length, in a circumferential direction, of an inner circumferential surface of a second tube, which is put onto a first tube that has conductivity, the first protrusion protruding from the inner circumferential surface of the second tube towards the first tube and being in contact, in a pressed state, with the first tube; and after forming the first protrusion, forming a second protrusion over the entire length of the inner circumferential surface in the circumferential direction, the second protrusion protruding towards a flexible shield that is inserted between the first tube and the second tube and holding the flexible shield between the first tube and the second tube. [0015] With the present disclosure, it is possible to suppress a localized increase in the size of the electromagnetic shield component, and it is also possible to suppress a localized increase in the size of the wire harness.

### BRIEF DESCRIPTION OF THE DRAWINGS

FIG. 1 is a diagram schematically showing the configuration of a wire harness of an embodiment of the present disclosure.

FIG. 2 is a partial cross-sectional view of the wire harness of the embodiment.

FIG. 3 is a cross-sectional view of an electromagnetic shield component of the embodiment.

FIG. 4 is an illustrative diagram for illustrating a method of manufacturing the electromagnetic shield component of the embodiment.

FIG. 5 is an illustrative diagram for illustrating the method of manufacturing the electromagnetic shield component of the embodiment.

FIGS. 6(a) and 6(b) are cross-sectional views of a reference example of the electromagnetic shield component.

### DETAILED DESCRIPTION OF EMBODIMENTS

Hereinafter, an embodiment of a wire harness will be described based on the drawings. Note that in the drawings, a configuration may be shown in a partially exaggerated or simplified manner for convenience of description.

Moreover, dimensional ratios of various portions may be different from actual dimensional ratios.

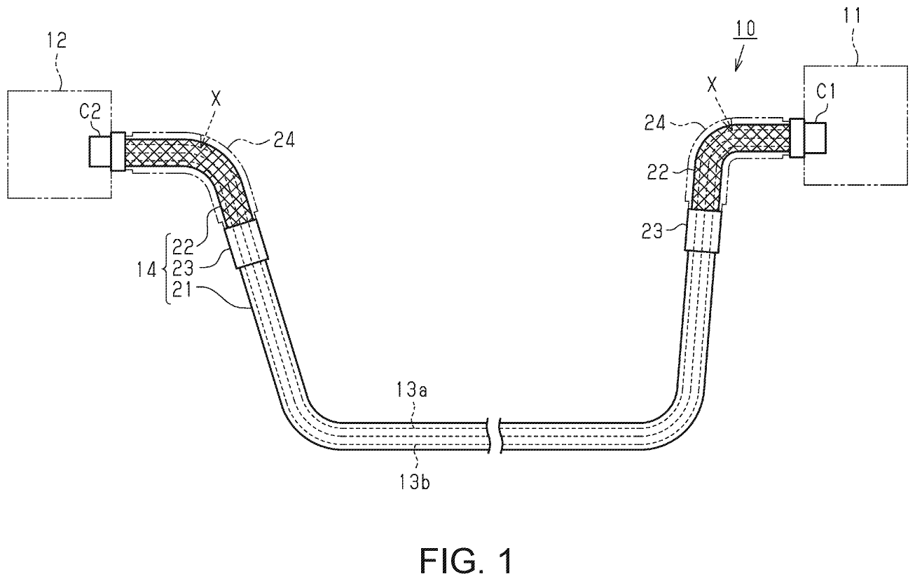

As shown in FIG. 1, in a hybrid vehicle, an electric automobile, or the like, a wire harness 10 of the present embodiment is routed so as to pass under the floor, for example, of the vehicle in order to connect, for example, a high-voltage battery 11 installed in a rear portion of the vehicle and an inverter 12 installed in a front portion of the vehicle to each other. The inverter 12 is connected to a wheel driving motor (not shown) serving as a power source for moving the vehicle, and generates an alternating-current power from a direct-current power of the high-voltage battery 11 and supplies the alternating-current power to the wheel driving motor. The high-voltage battery 11 is a battery capable of supplying a voltage of several hundred volts.

The wire harness 10 includes two high-voltage wires 13a and 13b connected to a positive terminal and a negative terminal, respectively, of the high-voltage battery 11, as well as a tubular electromagnetic shield component 14 that collectively encloses the high-voltage wires 13a and 13b.

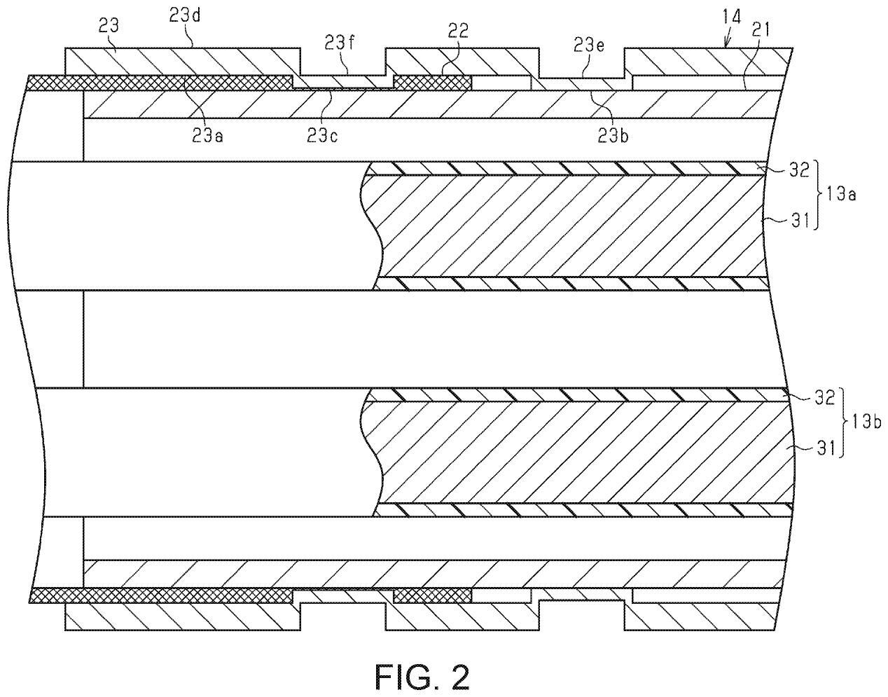

As shown in FIG. 2, each of the high-voltage wires 13a and 13b is a coated wire in which a core wire 31 made of a conductor is coated with an insulating coating 32 made of a resin material. The insulating coating 32 is formed on an outer circumferential surface of the core wire 31 through extrusion coating, and coats the outer circumferential surface of the core wire 31 while being in close contact therewith.

The high-voltage wires 13a and 13b are so-called non-shielded wires that do not have shielding structures, and can withstand high voltages and high currents. The high-voltage wires 13a and 13b are inserted into the electromagnetic shield component 14. End portions on one side of the high-voltage wires 13a and 13b end in a connector C1 that is connected to the high-voltage battery 11, and end portions on the other side of the high-voltage wires 13a and 13b end in a connector C2 that is connected to the inverter 12.

The electromagnetic shield component 14 has an elongated tubular shape as a whole. Moreover, an intermediate portion of the electromagnetic shield component 14 in a lengthwise direction thereof is formed of a metal pipe 21, and regions of the electromagnetic shield component 14 excluding the portion formed of the metal pipe 21 and including both end portions in the lengthwise direction are formed of braided members 22, which are flexible shielding members.

The metal pipe 21 is formed in a substantially perfectly cylindrical tubular shape. The metal pipe 21 is composed of an aluminum-based metal material, for example. The metal pipe 21 is routed so as to pass under the floor of the vehicle and is bent into a predetermined shape appropriate for the under-floor configuration. The metal pipe 21 collectively shields the high-voltage wires 13a and 13b that are inserted therein, and protects the high-voltage wires 13a and 13b from a flying stone and the like.

The braided members 22 are tubular members formed by braiding a plurality of metal strands. The metal strands of the braided members 22 can be composed of the same metal material as the metal pipe 21. In the present embodiment, the metal strands of the braided members 22 and the metal pipe 21 are composed of an aluminum-based metal material.

As shown in FIGS. 1 and 2, the braided members 22 of the present embodiment are inserted between fitting pipes 23 and the metal pipe 21, and are connected, by the fitting pipes 23, to the respective end portions of the metal pipe 21 in the lengthwise direction.

Moreover, as shown in FIG. 1, an outer circumferential surface of each braided member 22 is enclosed by an exterior material 24 such as a corrugated tube, for example.

The high-voltage wires 13a and 13b are led out from the end portions of the metal pipe 21, and include outside-the-pipe sections X that are not covered by the metal pipe 21. The braided members 22 collectively enclose the outer circumferences of the outside-the-pipe sections X of the high-voltage wires 13a and 13b. Thus, the outside-the-pipe sections X of the high-voltage wires 13a and 13b are electromagnetically shielded by the braided members 22.

Each fitting pipe 23 is formed in a substantially perfectly cylindrical tubular shape. The inner diameter of the fitting pipes 23 is larger than the outer diameter of the corresponding end portion of the metal pipe 21, so that the fitting pipes 23 can be put onto the metal pipe 21.

The fitting pipes 23 are composed of the same aluminum-based metal material as the metal material of the metal pipe 21. The fitting pipes 23 are configured to be fitted to the metal pipe 21 with the braided members 22 disposed between the metal pipe 21 and the respective fitting pipes 23.

As shown in FIG. 2, each fitting pipe 23 has a first protruding portion 23b (first protrusion) and a second protruding portion 23c (second protrusion) that protrude from an inner circumferential surface 23a of the fitting pipe 23 toward the inner side thereof in the radial direction. The protruding portions 23b and 23c may be a single protruding portion. The protruding portions 23b and 23c are provided over the entire length of the inner circumferential surfaces 23a of the fitting pipes 23.

The first protruding portion 23b protrudes toward the metal pipe 21 and is in contact with the metal pipe 21. That is to say, members such as the braided member 22 are not disposed between the first protruding portion 23b and the metal pipe 21.

The second protruding portion 23c protrudes toward the metal pipe 21 and is in contact with the braided member 22, and the braided member 22 is thereby held between the fitting pipe 23 and the metal pipe 21. Thus, the braided member 22 and the metal pipe 21 are electrically connected to each other.

Also, the protruding amount of the first protruding portion 23b from the inner circumferential surface 23a is larger than the protruding amount of the second protruding portion 23c from the inner circumferential surface 23a.

Here, the protruding portions 23b and 23c are formed on the inner circumferential surface 23a of the fitting pipe 23 by, for example, rotating the fitting pipe 23 and a jig, which is not shown, relative to each other to cause the jig to come into contact with the fitting pipe 23 from the outer side, and thereby plastically deforming the fitting pipe 23 in such a manner as to reduce the diameter thereof. Examples of the processing method for this plastic deformation include spinning and swaging. Consequently, by forming the protruding portions 23b and 23c, groove portions 23e and 23f are formed in an outer circumferential surface 23d of the fitting pipe 23 at a position corresponding to the protruding portions 23b, 23c. That is to say, the outer diameter of the fitting pipe 23 in the portions where the protruding portions 23b and 23c are formed is smaller than the outer diameter of the fitting pipe 23 in the portions where the protruding portions 23b and 23c are not formed.

The protruding portions 23b and 23c and the groove portions 23e and 23f are formed at positions that are spaced apart from the end portions of the fitting pipe 23 and are positions that are not end portions, that is, they are formed at positions that are in the middle of the fitting pipe 23. In other words, non-reduced-diameter sections are located on both sides of the groove portions 23e and 23f in the lengthwise direction of the fitting pipe 23.

Moreover, the wall thickness of the fitting pipe 23 in the portions thereof where the protruding portions 23b and 23c are formed is smaller than, for example, the wall thickness of the fitting pipe 23 in the portions thereof where the protruding portions 23b and 23c are not formed. Also, in the present example, the metal pipe 21 is not deformed (reduced in diameter) at positions corresponding to the protruding portions 23b and 23c of the fitting pipe 23. In other words, in the present example, the protruding amount of the protruding portions 23b and 23c of the fitting pipe 23 is set so as not to deform (reduce the diameter of) the metal pipe 21. Note that it is also possible to deform (reduce the diameter of) the metal pipe 21 at positions corresponding to the protruding portions 23b and 23c by setting a large protruding amount of the protruding portions 23b and 23c.

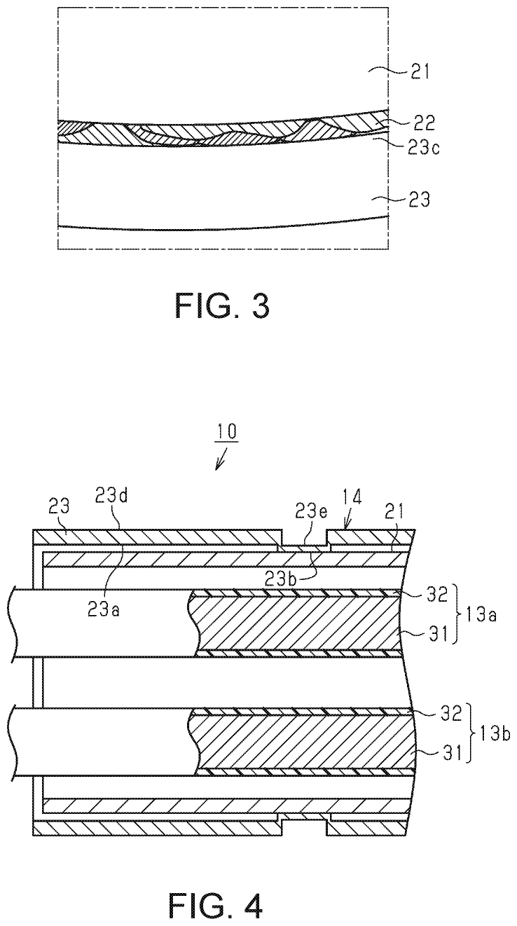

As shown in FIG. 3, strands of the braided member 22 are pressed and flattened by the second protruding portion 23c of the fitting pipe 23. For example, the strands of the braided member 22 that are pressed by the second protruding portion 23c are spread out in the circumferential direction of the fitting pipe 23 and flattened into a sheet-like shape. The strand diameter in the radial direction of the strands of the braided member 22 that are flattened by the protruding portion 23c is set to be equal to or smaller than half of the strand diameter in the radial direction of strands of the braided member 22 that are not flattened by the protruding portion 23c for example. Moreover, the strand diameter in the circumferential direction of the strands of the braided member 22 that are flattened by the second protruding portion 23c is set to be equal to or larger than double the strand diameter in the circumferential direction of the strands of the braided member 22 that are not flattened by the second protruding portion 23c, for example. Here, meshes (gaps between strands) of the braided member 22 are filled with the strands that are spread out in the circumferential direction. In other words, the gap between the fitting pipe 23 (second protruding portion 23c) and the metal pipe 21 is reduced by flattening the strands of the braided member 22 with use of the second protruding portion 23c. Thus, the area of contact between the outer circumferential surface of the metal pipe 21 and the braided member 22 is increased. In the example shown in FIG. 3, the strands of the braided member 22 are flattened by the second protruding portion 23c to such an extent that the meshes (gaps between strands) of the braided member 22 are no longer present. Note that the amount of flattening of the strands of the braided member 22, and the size of the meshes of the braided member 22, can be set by adjusting the protruding amount (depth of the groove portion 23f) of the second protruding portion 23c.

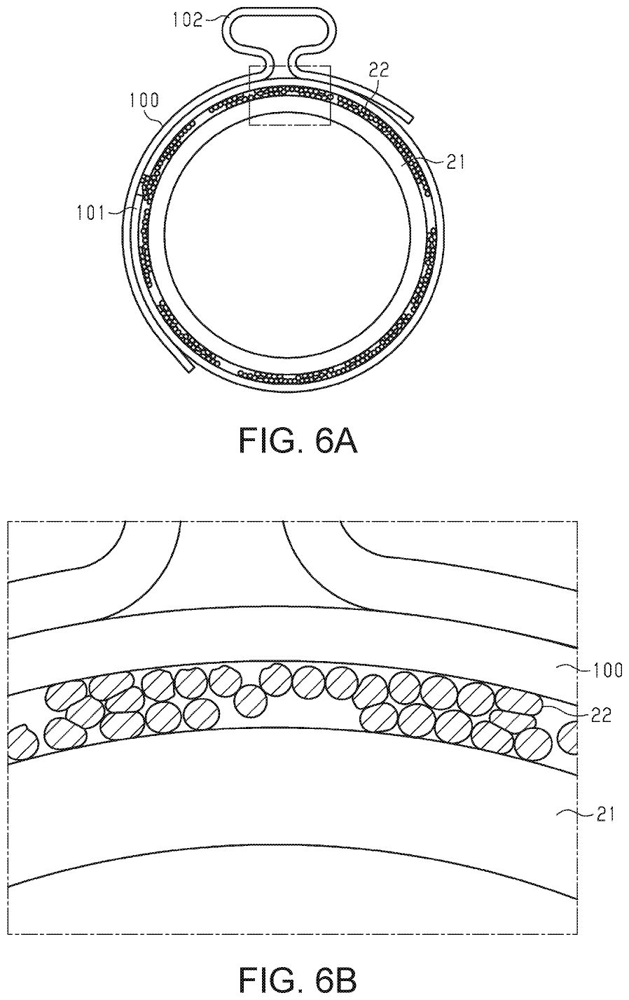

In a reference example shown in FIGS. 6(a) and 6(b), the metal pipe 21 and the braided member 22 are made to come into contact with each other and are thereby electrically connected to each other using a crimp ring 100. The crimp ring 100 has, as shown in FIGS. 6(a) and 6(b), a configuration including a circular arc-shaped portion 101 that extends along a circumferential wall of the metal pipe, and a bent and protruding portion 102 that is bent and protrudes toward the outer side of the metal pipe in such way that is bent from both ends of the circular arc-shaped portion 101. In other words, in the crimp ring, the diameter (inner diameter) of the circular arc-shaped portion 101 can be changed according to the plastic processing of the bent and protruding portion 102. As can be understood from FIG. 6, in the case where the braided member 22 and the metal pipe 21 are connected to each other using the crimp ring 100, the amount of deformation of the strands of the braided member 22 is slight compared with the configuration of the present example shown in FIG. 3. That is to say, according to the configuration of the present example, the area of contact between the braided member 22 and the outer circumferential surface of the metal pipe 21 increases as a result of the strands of the braided member 22 being pressed and flattened, and therefore, the contact reliability can be improved.

The following is a description of a method of manufacturing the electromagnetic shield component 14 of the wire harness 10 that is configured as described above.

As shown in FIG. 4, in a state in which the fitting pipe 23 is put on the metal pipe 21, the first protruding portion 23b is formed through spinning, swaging, or the like as described above, at a predetermined position that is spaced apart from the end portions of the fitting pipe 23. At this time, the first protruding portion 23b comes into contact, in a pressed state, with the metal pipe 21.

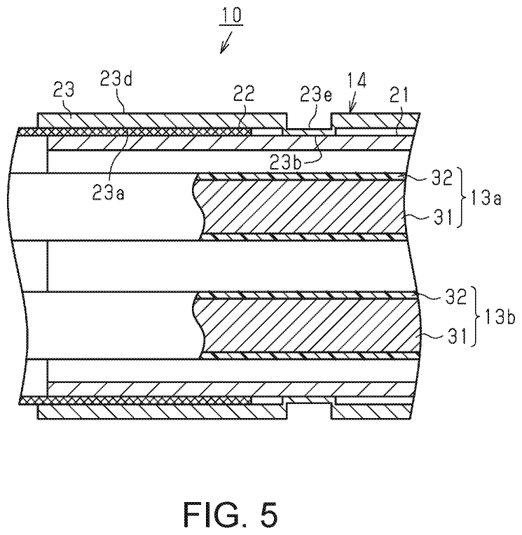

As shown in FIG. 5, the braided member 22 is inserted between the outer surface of the metal pipe 21 and the inner circumferential surface 23a of the fitting pipe 23. Next, the second protruding portion 23c is formed through the previously-described spinning, swaging, or the like at a position that is spaced apart from the end portions of the fitting pipe 23 and is a position at which the second protruding portion 23c can press the braided member 22. At this time, the second protruding portion 23c is formed such that the braided member 22 is squashed between the metal pipe 21 and the second protruding portion 23c. Thus, the electromagnetic shield component 14 as shown in FIG. 2, in which the braided member 22 is held between the fitting pipe 23 and the metal pipe 21 by the second protruding portion 23c, is complete.

Next, the workings of the present embodiment will be described.

In the wire harness 10 of the present embodiment, the braided members 22 are disposed between the metal pipe 21 serving as a first tubular member (first tube) and the fitting pipes 23 serving as second tubular members (second tube), and in this state, the diameter of a portion of each of the fitting pipes 23 is reduced through, for example, spinning, swaging, or the like to thereby form the second protruding portions 23c on the inner circumferential surfaces 23a thereof. These second protruding portions 23c are configured to protrude from the inner circumferential surfaces 23a of the fitting pipes 23 toward the braided members 22 that are inward in the radial direction. Therefore, the braided members 22 are held between the protruding portions 23c and the metal pipe 21, and the metal pipe 21 and the braided members 22 are thus electrically connected to each other.

Moreover, the fitting pipes 23 of the present embodiment have the groove portions 23e and 23f formed in the outer circumferential surfaces 23d thereof through spinning, swaging, or the like, but this configuration does not include a member that protrudes locally from the outer circumferential surfaces 23d of the fitting pipes 23 towards the outer side thereof in the radial direction, and therefore it is possible to suppress a localized increase in the size of the electromagnetic shield component 14.

Also, the fitting pipes 23 of the present embodiment are provided with the first protruding portions 23b on the inner circumferential surfaces 23a thereof, by reducing the diameters of portions of the fitting pipes 23 through, for example, spinning, swaging, or the like. These first protruding portions 23b are configured to protrude from the inner circumferential surfaces 23a of the fitting pipes 23 toward the metal pipe 21, which is the inner side in the radial direction thereof. Thus, the fitting pipes 23 can be securely fixed to the metal pipe 21. For this reason, it is possible to suppress the load that is applied to the braided members 22 from the second protruding portions 23c.

Also, with the present embodiment, the first protruding portions 23b are formed farther forward than the second protruding portions 23c are, and the fitting pipes 23 are each fixed to the metal pipe 21, and therefore the fitting pipes 23 can be suppressed from rotating relative to the metal pipe 21 even in a case where spinning, swaging, or the like is used such as in the present example. Here, if for example the fitting pipes 23 rotate relative to the metal pipe 21, it becomes likely that the strands of the braided members 22 will be subjected to a load and break when the second protruding portions 23c are formed. However, as previously described, the first protruding portions 23b are formed farther forward than the second protruding portions 23c are, and the fitting pipes 23 are each fixed to the metal pipe 21, thus the fitting pipes 23 can be suppressed from rotating relative to the metal pipe 21, and therefore it is possible to suppress breakage of the strands of the braided members 22 and to maintain the electromagnetic shielding effect.

Next, the effects of the present embodiment will be described.

(1) The second protruding portion 23c is included, which protrudes from the inner circumferential surface 23a of the fitting pipe 23 that is positioned on the outer side of the metal pipe 21 towards the braided member 22 and holds the braided member 22 between the fitting pipe 23 and the metal pipe 21. Therefore, the braided member 22 can be held between the fitting pipe 23 and the metal pipe 21 by the second protruding portion 23c. Consequently, a conventional bent and protruding portion can be made unnecessary, and thus, a localized increase in the size of the electromagnetic shield component 14 can be suppressed.

(2) The second protruding portion 23c is provided over the entire length in the circumferential direction of the inner circumferential surface 23a of the fitting pipe 23, which is the pipe located on the outer side of the fitting pipe 23 and the metal pipe 21, and can therefore apply a substantially uniform pressure to the braided member 22.

(3) The fitting pipe 23 has the first protruding portion 23b that is in contact, in a pressed state, with the metal pipe 21, and therefore it is possible to fix the fitting pipe 23 to the metal pipe 21.

(4) The outer diameter of the fitting pipe 23 in the portion where the protruding portion 23b is formed is smaller than the outer diameter of the fitting pipe 23 in portions where the protruding portion 23b is not formed. In other words, the protruding portion 23b can be obtained by reducing the diameter of the fitting pipe 23 through plastic processing.

(5) Since the fitting pipe 23 is composed of an aluminum-based metal material, a reduction in the weight of the fitting pipe 23 can be achieved, and favorable workability can be realized when forming the protruding portion 23b or the like.

(6) Since the braided member 22, the metal pipe 21, and the fitting pipe 23 are composed of the same metal material, the occurrence of galvanic corrosion between those members can be suppressed. In particular, as in the present embodiment, in the case of a non-waterproof structure in which a connecting portion between the braided member 22 and the metal pipe 21 serving as the first tubular member is not provided with a cover made of rubber that covers the connecting portion, it is possible to suppress an increase in the number of components while suppressing the occurrence of galvanic corrosion. Moreover, in the present example, since the braided member 22, the metal pipe 21, and the fitting pipe 23 are composed of an aluminum-based metal material, a weight reduction can be achieved.

(7) Since the tubular braided member 22 is employed as a flexible shielding member (flexible shield), the outer side of the metal pipe 21 can be covered, and an electromagnetic shielding effect can be obtained.

Note that the foregoing embodiment may also be changed as follows.
The foregoing embodiment is configured with one first protruding portion 23b and one second protruding portion 23c provided on each fitting pipe 23, but a configuration may be employed in which at least one of the first or second protruding portions 23b and 23c are provided in plurality.
Although not specifically mentioned in the foregoing embodiment, for example, the metal pipe 21, the braided member 22, and the fitting pipe 23 may also be composed of materials that have different degrees of hardness. In this case, by forming the fitting pipe 23 that is located on the outer side using a relatively soft material, the fitting pipe 23 can be actively deformed during the formation of the protruding portion 23b, and the amounts of deformation of the metal pipe 21 and the braided member 22 can be suppressed. Note that in the case of such a configuration, the metal pipe 21, the braided member 22, and the fitting pipe 23 may or may not be composed of the same metal material.
In the foregoing embodiment, the metal pipe 21 serving as the first tubular member and the fitting pipe 23 serving as the second tubular member have a substantially perfectly cylindrical tubular shape, but one or both of the first and second tubular members may also have an elliptical tubular shape. Examples of the first tubular member having an elliptical tubular shape include a connector shielding shell that covers the connector C1, and the like.
In the foregoing embodiment and the foregoing modifications, a configuration is adopted in which the fitting pipe 23 is put onto the metal pipe 21, but a configuration may also be adopted in which the metal pipe 21 is put on the fitting pipe 23. That is to say, the inner diameter of the metal pipe 21 is set to be larger than the outer diameter of the fitting pipe 23, and the fitting pipe 23, the braided member 22, and the metal pipe 21 are arranged in that order from the inner side in the radial direction. In this case, the first and second protruding portions are provided on the inner circumferential surface of the metal pipe 21.
In the foregoing embodiment and the foregoing modifications, the configuration is adopted in which the braided member 22 is employed as the flexible shielding member, but the braided member 22 may be changed to a metal sheet, a metal woven fabric, or the like.
In the foregoing embodiment and the foregoing modifications, the metal pipe 21 may also be changed to a shielding pipe having a structure in which, for example, a conductive shielding layer and an resin outer layer are laminated in that order on an outer circumferential surface of a pipe main body made of a nonmetal (resin or the like). In this case, in a portion where the resin outer layer is partially removed to expose the conductive shielding layer, the shielding layer and the braided member 22 may be electrically connected to each other using the fitting pipe 23.

Moreover, the fitting pipe 23 may be inserted to the metal pipe 21. In this case, in a portion where the pipe main body, which is an inner layer, is partially removed to expose the conductive shielding layer, the shielding layer and the braided member 22 may be electrically connected to each other using the fitting pipe 23.
Although not specifically mentioned in the foregoing embodiment and the foregoing modifications, a configuration may also be adopted in which a cover made of rubber is inserted and attached to the connecting portion between the metal pipe 21 and the braided member 22, the cover covering an outer circumferential surface of the connecting portion and suppressing the entry of water therethrough.
In the foregoing embodiment and the foregoing modifications, the braided member 22, the metal pipe 21, and the fitting pipe 23 are composed of an aluminum-based metal material, but there is no limitation to this. The braided member 22, the metal pipe 21, and the fitting pipe 23 may also be composed of different conductive materials. Moreover, the braided member 22, the metal pipe 21, and the fitting pipe 23 may also be composed of the same conductive material other than an aluminum-based metal material.
The wire harness 10 of the foregoing embodiment has a configuration in which the two high-voltage wires 13a and 13b are inserted in the electromagnetic shield component 14, but the configuration of a wire inserted in the electromagnetic shield component 14 may be appropriately changed depending on the configuration of the vehicle. For example, a configuration may also be adopted in which a power supply low-voltage wire for connecting a low-voltage battery having a rated voltage of 12 V or 24 V to various types of low-voltage devices (e.g., a lamp, a car audio system, and the like) and driving the various types of low-voltage devices is added as a wire inserted in the electromagnetic shield component 14.
The arrangement relationship between the high-voltage battery 11 and the inverter 12 in the vehicle is not limited to that of the foregoing embodiment, and may be appropriately changed depending on the configuration of the vehicle. Moreover, in the foregoing embodiment, the high-voltage battery 11 is connected to the inverter 12 via the high-voltage wires 13a and 13b, but a configuration may also be adopted in which the high-voltage battery 11 is connected to a high-voltage device other than the inverter 12.
In the foregoing embodiment, the wire harness 10 is configured such that the high-voltage battery 11 and the inverter 12 are connected to each other, but the wire harness 10 can also be configured to electrically connect a plurality of devices, of any power source apparatus and any load apparatus, such as a configuration in which the wire harness 10 is configured to connect the inverter 12 and a wheel driving motor to each other.
The foregoing embodiment and variations thereof may be combined as appropriate.

The metal pipe 21 of the embodiment may be, for example, configured to maintain a predetermined shape that has a single or plurality of linear portions, a single or plurality of bent portions, and an internal space for loosely inserting one or more wires, and the metal pipe 21 may be referred to as a wire protecting pipe that has a higher rigidity than the braided member 22.

The fitting pipe 23 of the embodiment may also be referred to as a plastically deformable fastening sleeve. The first protruding portion 23b is provided in the lengthwise direction of the fitting pipe 23 at a first predetermined position at which the braided member 22 and the metal pipe 21 do not overlap. The second protruding portion 23c is provided in the lengthwise direction of the fitting pipe 23 at a second predetermined position at which the braided member 22 and the metal pipe 21 overlap. The first protruding portion 23b and the second protruding portion 23c may each be referred to as an inward-protruding annular ridge that continuously extends, without interruption, in the circumferential direction of the fitting pipe 23. The innermost surfaces, that is the top surfaces, of the first protruding portion 23b and the second protruding portion 23c can have predetermined widths in the lengthwise direction of the fitting pipe 23, and may also be smooth surfaces, for example. The smooth innermost surface of the second protruding portion 23c firmly fastens the braided member 22 to the metal pipe 21 while suppressing breakage of the braided member 22, and is therefore advantageous. The second protruding portion 23c is separated from the first protruding portion 23b in the lengthwise direction of the fitting pipe 23. Regions that exclude the first protruding portion 23b and the second protruding portion 23c in the inner circumferential surface 23a of the fitting pipe 23 may also be referred to as non-protruding surfaces. As shown in FIG. 2, the inner circumferential surface 23a of the fitting pipe 23 has non-protruding surfaces between a first open end (the left end of the fitting pipe 23 in FIG. 2) of the fitting pipe 23 and a second protruding portion 23c between the second protruding portion 23c and a first protruding portion 23b and between the first protruding portion 23b and a second open end (the right end of the fitting pipe 23, which is not shown) of the fitting pipe 23. The first protruding portion 23b of the fitting pipe 23 comes into direct contact with the outer surface of the metal pipe 21, but is not in direct contact with the outer surface of the braided member 22. The second protruding portion 23c of the fitting pipe 23 comes into direct contact with the outer surface of the braided member 22, but does not come into direct contact with the outer surface of the metal pipe 21.

As a result of the second protruding portion 23c of the fitting pipe 23 locally compressing the braided member 22 towards the outer surface of the metal pipe 21, the braided member 22 includes, between the non-protruding surface of the fitting pipe 23 and the outer surface of the metal pipe 21, a first thickness non-compressed or low compression annular portion that is arranged in a non-compressed state or a low compression state, and a second thickness annular compressed portion that is compressed by the second protrusion 23c of the fitting pipe 23 and the outer surface of the metal pipe 21 and is thinner than the first thickness non-compressed or low compression annular portion. The braided member 22 has steps formed thereon, which are formed by the non-compressed or low compression annular portion and the annular compressed portion.

The present disclosure encompasses the following implementation examples, in which the reference numerals of the constituent elements of the embodiment are used in order to facilitate the understanding rather than for restriction.

Additional Remark 1: An electromagnetic shield component (14) of some implementation examples includes:

a wire protecting pipe (21) having an end portion and an internal space in which at least one wire (13a, 13b) is loosely inserted;

a tubular flexible shielding member (22) that covers an outer surface of the wire protecting pipe (21) from the end portion of the wire protecting pipe (21) so as to overlap with the wire protecting pipe (21) for a certain overlap length; and

a fastening sleeve (23) that is arranged to cover an overlap portion in which the flexible shielding member (22) and the wire protecting pipe (21) overlap, and a non-overlap portion in which the flexible shielding member (22) and the wire protecting pipe (21) do not overlap, wherein

the inner surface of the fastening sleeve (23) includes:
a first inward-protruding annular ridge (23b) that extends continuously in the circumferential direction without interruption;
a second inward-protruding annular ridge (23c) that is provided spaced apart from the first inward-protruding annular ridge (23b) in the lengthwise direction of the fastening sleeve (23), and extends continuously in the circumferential direction without interruption; and
a non-protruding surface between the first inward-protruding annular ridge (23b) and the second inward-protruding annular ridge (23c), and

the first inward-protruding annular ridge (23b) is configured to come into direct contact with an outer surface of the wire protecting pipe (21) in the non-overlap portion, and fasten the fastening sleeve (23) to the wire protecting pipe (21) by pressing the outer surface of the wire protecting pipe (21), and

the second inward-protruding annular ridge (23c) is configured to come into direct contact with an outer surface of the flexible shielding member (22) in the overlap portion, and fasten the flexible shielding member (22) to the wire protecting pipe (21) by compressing the flexible shielding member (22) in co-operation with the outer surface of the wire protecting pipe (21).

Additional Remark 2: With some implementation examples,

in a state in which the fastening sleeve (23) fastens the flexible shielding member (22) and the wire protecting pipe (21) to each other, the flexible shielding member (22) includes:

a non-compressed or low compression annular portion having a first thickness and being arranged, in a state of non-compression or low compression, between the non-protruding surface of the fastening sleeve (23) and the outer surface of the wire protecting pipe (21); and

an annular compressed portion having a second thickness that is thinner than the first thickness and being compressed by the second inward-protruding annular ridge (23c) of the fastening sleeve (23) and the outer surface of the wire protecting pipe (21).

Additional Remark 3: With some implementation examples, the flexible shielding member (22) includes a step that is formed by the non-compressed or low compression annular portion and the annular compressed portion.

Additional Remark 4: With some implementation examples, when the fastening sleeve (23) is viewed in the lengthwise direction thereof, the first inward-protruding annular ridge (23b) has a first constant height, and the second inward-protruding annular ridge (23c) has a second constant height that is lower than the first constant height.

Additional Remark 5: In some implementation examples, the second inward-protruding annular ridge (23c) is parallel to the first inward-protruding annular ridge (23b).

Additional Remark 6: In some implementation examples, the flexible shielding member (22) is a conductive braided member.

Additional Remark 7: In some implementation examples, the wire protecting pipe (21) is a conductive metal tube that is configured to maintain a predetermined shape that has a single or plurality of linear portions, a single or plurality of bent portions, and an internal space for loosely inserting one or more wires.

It will be apparent to those skilled in the art that the present disclosure may be embodied in other specific forms without departing from the technical ideas thereof. For example, some of the components described in the embodiment (or one or more variations thereof) may be omitted, or some of the components may be combined. The scope of the disclosure should be defined with reference to the appended claims, along with the full scope of equivalents to which the appended claims are entitled.

1. An electromagnetic shield component, comprising:
a first tube that has conductivity;
a flexible shield; and
a second tube that is put onto the first tube in a state in which the flexible shield is disposed between the first tube and the second tube,
wherein the second tube, in an inner circumferential surface thereof, has a first protrusion that protrudes toward the first tube and is in contact with the first tube in a pressed state, and a second protrusion that protrudes toward the flexible shield and holds the flexible shield between the first tube and the second tube, and
the first and second protrusions are provided over an entire length of the inner circumferential surface in a circumferential direction.

2. The electromagnetic shield component according to claim 1,
wherein an outer diameter of the second tube in portions thereof where the first and second protrusions are formed is smaller than an outer diameter of the second tube in portions thereof where the first and second protrusions are not formed.

3. The electromagnetic shield component according to claim 1,
wherein a protruding amount of the first protrusion from the inner circumferential surface is larger than a protruding amount of the second protrusion from the inner circumferential surface.

4. A wire harness comprising:
the electromagnetic shield component according to claim 1, and
a wire inserted in the electromagnetic shield component.

5. A method of manufacturing an electromagnetic shield component, comprising:
forming a first protrusion over an entire length, in a circumferential direction, of an inner circumferential surface of a second tube, which is put onto a first tube that has conductivity, the first protrusion protruding from the inner circumferential surface of the second tube towards the first tube and being in contact, in a pressed state, with the first tube; and
after forming the first protrusion, forming a second protrusion over the entire length of the inner circumferential surface in the circumferential direction, the second protrusion protruding towards a flexible shield that is inserted between the first tube and the second tube and holding the flexible shield between the first tube and the second tube.
